(19) United States
(12) Patent Application Publication
(10) Pub. No.: US 2009/0072250 A1
(43) Pub. Date: Mar. 19, 2009

(54) CHIP TYPE SEMICONDUCTOR LIGHT EMITTING DEVICE

(75) Inventor: Tomio Inoue, Kagoshima (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi (JP)

(21) Appl. No.: 12/282,104

(22) PCT Filed: Mar. 7, 2007
(86) PCT No.: PCT/JP2007/054409

§ 371 Date: Oct. 6, 2008

(30) Foreign Application Priority Data
Mar. 8, 2006 (JP) 2006-062691

(51) Int. Cl. H01L 33/00

(52) U.S. Cl. 257/88; 257/E33.067

(57) ABSTRACT

There is provided a reflective chip type semiconductor light emitting device, which has improved efficiency of taking out light and further improved luminance with the same input, and which emits high luminance light by emitting light uniformly from an area as large as possible and is suitable for lighting apparatuses. A pair of terminal electrodes (11, 12) is provided at the both end portions of one surface (front surface) of a substrate (1) so as to be electrically separated, and a plurality of LED chips (2) are separately provided on the one surface (front surface) of the substrate (1). Each of the LED chips (2) is electrically connected to a first terminal electrode (11) through a first bonding section (11a), and to a second terminal electrode (12) through a wire (7) and a second bonding section (12a), respectively. A reflecting wall (3) is provided so as to surround a circumference of each of the plurality of LED chips (2) on the one surface (front surface) of the substrate (1).

### FIELD OF THE INVENTION

The present invention relates to a chip type (surface mount type) semiconductor light emitting device which is provided with a pair of terminal electrodes (including leads) at both end portions on a substrate and a plurality of light emitting device chips (hereinafter referred to as LED chips) on the substrate. More particularly, the present invention relates to a chip type semiconductor light emitting device in which, even in a semiconductor light emitting device capable of high luminance light emitting with high current drive and an enlarged light emitting area, high luminance can be obtained by improving efficiency of taking out light further.

### BACKGROUND OF THE INVENTION

For example, a chip type semiconductor light emitting device by the prior art is formed, as shown in FIG. 5(a), by providing a pair of terminal electrodes 42 and 43 at both end portions of a substrate 41 made of a BT resin or the like so as to be extended to a back surface of the substrate 41, connecting a lower electrode of a LED chip 44 to one terminal electrode 42 by die-bonding the LED chip 44 on the one terminal electrode 42, and connecting an upper electrode of the LED chip 44 to another terminal electrode 43 with a wire 45. A surrounding thereof is surrounded with a reflecting case 46, which is formed of a resin made of a liquid polymer or the like, so as to reflect light toward a front side, and a sealing resin layer 47 is formed by filling a light transmitting resin inside (cf. for example PATENT DOCUMENT 1).

In addition, in recent years, since development of a white semiconductor light emitting device has been advanced and semiconductor light emitting devices have been used for lighting apparatuses or the like, as for the chip type semiconductor light emitting device, further improving of luminance is expected and high current drive has been realized with enlarging a chip size and, at the same time, increasing input power. Therefore, since heat generation in LED chips increases, it is necessary to inhibit lowering of the luminance caused by thermal saturation even when high current is applied and also to improve heat dissipation characteristics. As an example of a semiconductor light emitting device for such high current use with a chip type (surface mount type), having a reflecting case at a surrounding, and having heat dissipation characteristics, a structure shown in FIG. 5(b) has been introduced.

Namely, in FIG. 5(b), a resin portion 52 integrating a reflecting case 57 with a substrate 51 at a surrounding of the substrate 51 which has a large thermal conductivity such as, for example, that of AlN, and an insulating property, is provided fixing a pair of leads 53 and 54, a LED chip 55 emitting, for example, blue light and having a large size of, for example, 0.9 mm×0.9 mm is mounted on the lead 53 of one side, and, similarly to the above-described example, a pair of electrodes of the LED chip 55 are electrically connected to the pair of leads 53 and 54 with a wire 56 made of gold or the like. A reflecting case 57 made of, for example, a white resin (for example, AMODEL) is formed at a surrounding of the LED chip 55 and a wire bonding portion, and the reflecting case 57 and the resin portion 52 are formed of the white resin by injection molding concurrently. Then, a portion of the LED chip 55 and the wire 56 surrounded by the reflecting case 57 is coated by a light color conversion resin layer 58 formed by coating a light color conversion resin containing a fluorescent material which converts a part of blue light into red light and green light in order to emit white light by mixing them.

### PATENT DOCUMENT 1: Japanese Patent Application Laid-Open No. 2001-177155

### DISCLOSURE OF THE INVENTION

### Problem to be Solved by the Present Invention

As described above, in a reflective chip type semiconductor light emitting device for high current drive by the prior art, luminance is improved by using a LED of a large chip size. However, if an area of the chip is increased, light emitted at a center portion of the chip and traveling laterally is absorbed by semiconductor layers and attenuates, and the luminance can not be improved sufficiently. In addition, even if a LED of a large size is used, the size has a limitation, then there is a problem such that luminance is not sufficient for a chip type semiconductor light emitting device for lighting apparatuses. Furthermore, in a lighting apparatus or the like which is required to light a large area uniformly, since an area emitting light is a small point shape of 0.9 mm square even if a chip size is increased, there is a problem such that the chip type semiconductor light emitting device is not suitable for surface light sources such as lighting apparatuses or the like. In addition, as quantity of heat generation accompanied with enhancing luminance increases remarkably, heat dissipation at a center portion of the LED chip deteriorates additionally by enlarging the chip size, and there arises a problem such that reliability is lowered by breakage of the LED chip or deterioration of characteristics, caused by heat.

In addition, if a metal plate or an AlN insulating substrate of a high thermal conductivity is used at a principal portion of the substrate of the chip type semiconductor light emitting device, not only there is a problem of processability or a cost, but also there is a problem such that sufficient heat dissipation can not be achieved if a material having a high thermal conductivity is not provided at a mounting board side on which the chip type semiconductor light emitting device is to be mounted so as to be contacted with the substrate of the chip type semiconductor light emitting device, even if the thermal conductivity of the substrate of the chip type semiconductor light emitting device is high. In addition, if the reflecting case exposed to the front surface side by a large area is formed with a white resin, a thermal conductivity of the reflecting case is small by 1/1,000 comparing to the metal plate, and heat dissipation characteristics from the reflecting case is very inferior, thereby there arises a problem such that the heat dissipation from the reflecting case is not sufficient. Further, if coefficients of thermal expansion of the substrate and the reflecting case are different, peeling between both occurs by heat cycles and the heat dissipation becomes more inferior.

The present invention is directed to solve the above-described problems and an object of the present invention is to provide a reflective chip type semiconductor light emitting device, which has improved efficiency of taking out light and further improved luminance with the same input, and which emits high luminance light by emitting light uniformly from an area as large as possible and is suitable for lighting apparatuses.

Another object of the present invention is to provide a reflective chip type semiconductor light emitting device capable of improving reliability against heat generation by further improving the heat dissipation from the entire of the chip type semiconductor light emitting device in addition to the above-described object.

### Means for Solving the Problem

A chip type semiconductor light emitting device according to the present invention includes a substrate, a pair of terminal electrodes provided electrically separately at both end portions of one surface of the substrate which are opposite to each other, a plurality of light emitting device chips provided separately on the one surface of the substrate and connected to the pair of terminal electrodes, and a reflecting wall provided so as to surround a surrounding of each of the plurality of light emitting device chips. Here, the terminal electrodes mean electrodes formed so as to be connected to electrodes of the LED chip and to be connected to the substrate or the like, and include electrodes formed with a metal film on the substrate, leads formed separately and provided on the substrate by adhesion or mounting, or the like.

At least a part of the reflecting wall is formed with a laminated body formed by coating a paste material, thereby the reflecting wall can be formed accurately even on a small region. In addition, the laminated body can be fixed by repeating coating and drying, and finally by baking or firing.

It is preferable that both of the substrate and the part of the reflecting wall are formed with a material whose principal material is a sintered body of alumina, because heat dissipation characteristics can be improved. Here, the principal material means that at least 50% or more of the substrate or the like is a sintered body of alumina, and other materials, impurities or the like may be included to some extent.

In addition, it is preferable that a through hole is formed at a position of the substrate where each of the light emitting device chips is to be provided and the through hole is filled with a material having a larger thermal conductivity than that of the substrate, because the heat dissipation characteristics can be more improved.

### EFFECT OF THE INVENTION

According to the present invention, in the reflective chip type semiconductor light emitting device, LED chips divided into a plurality of chips are provided on separated regions of the substrate, and a surrounding of each of the LED chips is surrounded by the reflecting wall (reflector), thereby an area of the chip sides increases compared to that in one large chip, a total quantity of light emitted from each side of the chips increases, and light upward increases suitably. Namely, in one chip with a large area, light emitted in a center portion and traveling laterally is apt to attenuate by being absorbed by semiconductor layers such as an active layer or the like, however, since the chips are divided into a small size in the present invention, light emitted in the center portion and traveling laterally is emitted from the side and reflected upward by the reflecting wall and can be utilized effectively. In addition, since not one LED chip but small divided LED chips are dispersed in a large area of the substrate, they acts not as light sources of a point shape but as a surface light source, and emit mild light suitable for lighting apparatuses. Further as for heat generation within the LED chips, since the reflecting wall which can dissipate the heat is respectively provided near the LED chips divided into a small size, the heat can be dissipated through the substrate and the reflecting wall at every small region and deterioration by heat can be inhibited.

In addition, since a sintered body of alumina which has a comparatively high thermal conductivity is used for the reflecting wall and the substrate, there exists no problem caused by a difference of thermal expansion between the substrate and the reflecting wall, and heat can be dissipated fast by approximately 100 times compared to a case of a white resin, while maintaining close contact. As a result, since the heat can be dissipated from exposed surfaces of the reflecting wall having a large area, and even in a case such as heat dissipation is not sufficient from the substrate (regardless of heat dissipation characteristics of the mounting board), the heat can be dissipated from the reflecting wall, the heat dissipation characteristics of the LED is significantly improved and reliability can be also improved remarkably. In addition, since the reflecting wall is formed of an inorganic material, a color of the reflecting wall hardly changes even its temperature is raised, and an excellently stable reflection coefficient can be maintained.

In addition, by forming a through hole at a position of the substrate where each of the light emitting device chips is to be provided and the through hole is filled with a material having a larger thermal conductivity than that of the substrate, since heat from the LED chip conducts to the mounting board rather through a filling material embedded in the through hole than the sintered body of alumina, thermal conductivity can be improved by the substrate, then, in case such that a member having high thermal conductivity is used for the mounting board, the heat dissipation can be improved through the member.

### BRIEF DESCRIPTION OF THE DRAWINGS

FIG. 1 is an explanatory figure of a plan view and a cross-sectional view explaining an embodiment of the chip type semiconductor light emitting device according to the present invention.

FIG. 2 is an explanatory figure of a plan view explaining an electrode pattern of the substrate using for the chip type semiconductor light emitting device according to the present invention.

FIG. 3 is an explanatory figure of a plan view and a cross-sectional view explaining another embodiment of the chip type semiconductor light emitting device according to the present invention.

FIG. 4 is an explanatory cross-sectional view explaining of a lamination structure of the LED chip shown in FIG. 1.

FIG. 5 is explanatory cross-sectional views showing examples of a chip type semiconductor light emitting device by the prior art.

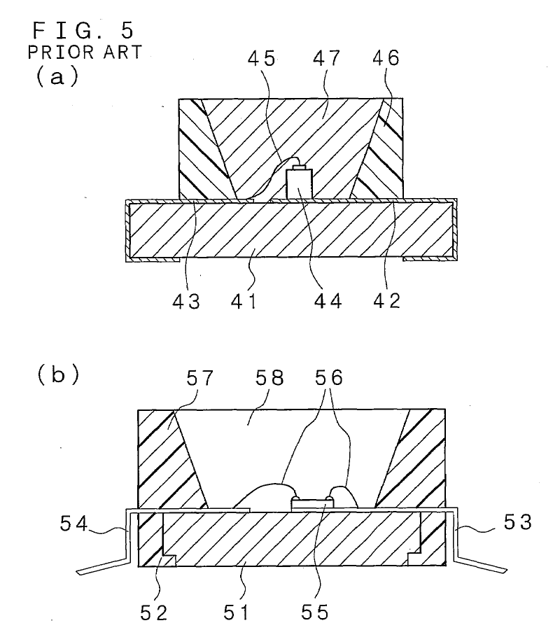

### EXPLANATION OF LTTERS AND NUMERALS

1: substrate
2: LED chip
3: reflection wall
4: through hole for heat dissipation
11: first terminal electrode
12: second terminal electrode

### THE BEST EMBODIMENT OF THE PRESENT INVENTION

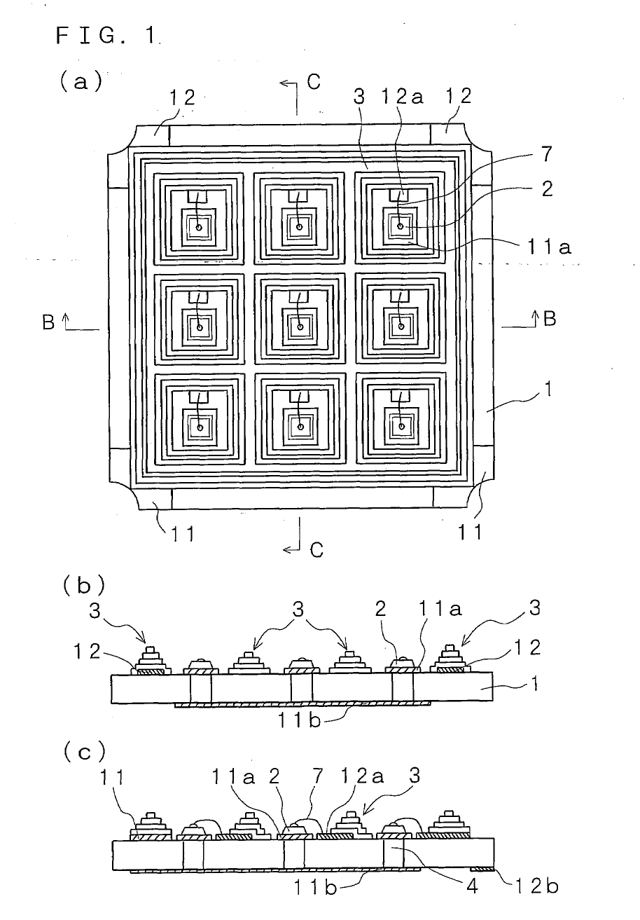

An explanation will be given below of an embodiment of a chip type semiconductor light emitting device according to the present invention in reference to the drawings. As explanatory figures of a plan view and cross-sectional views (cross-sectional views at B-B and C-C of FIG. 1(a)) of an embodiment of the chip type semiconductor light emitting device are shown respectively in FIG. 1, a pair of terminal electrodes 11 and 12 is provided at the both end portions of one surface (front surface) of a substrate 1 which are in opposite sides to each other so as to be electrically separated, and a plurality (nine chips in the example shown in FIG. 1) of light emitting device chips (LED chips) 2 are separately provided on the one surface (front surface, namely a plurality of first bonding sections 11a which are electrically connected to the first terminal electrode 11 through a back surface electrode 11b in the example shown in FIG. 1) of the substrate 1. And a pair of electrodes of each of the LED chips 2 is electrically connected to the first terminal electrode 11 through the first bonding section 11a, and to the second terminal electrode 12 through a wire 7 and a second bonding section 12a, respectively, and a reflecting wall 3 is provided so as to surround a surrounding of each of the plurality of LED chips 2 on the one surface (front surface) of the substrate 1. In addition, in the example shown in FIG. 1, the first bonding sections 11a are formed at parts where the LED chips 2 are to be provided on the substrate 1 made of a sintered body of alumina as described later, and through holes are formed under the first bonding sections 11a respectively. Through holes 4 for heat dissipation are formed by filling the through holes (via contacts) with a material such as silver or the like having a larger thermal conductivity than that of the substrate 1, and lower electrodes of the LED chips 2 are electrically connected to the first terminal electrodes 11 through the first bonding sections, the through holes 4 for heat dissipation and the back surface electrode 11b provided on the back surface of the substrate.

A substrate made of a sintered material of alumina is used for the substrate 1, and a thickness thereof is similar to that of a usual chip type semiconductor light emitting device and may be approximately 0.06 to 0.5 mm. The substrate 1 is formed by sintering a green sheet having a thickness of approximately 0.3 mm, and, by forming metal films of the first and second terminal electrodes 11 and 12, through holes la and 4 or the like, described later, the substrate provided with the metal films or the like can be obtained by sintering. If reflecting walls 3 described later are formed with laminated bodys with alumina powder of a paste state, at the time of sintering, the reflecting walls 3 can be concurrently formed of alumina by sintering. The light emitting device shown in FIG. 1(a) is formed with a size (outer shape) which has (length)×(width)×(height) of approximately (3 to 5 mm)×(3 to 5 mm)×(1 to 3 mm).

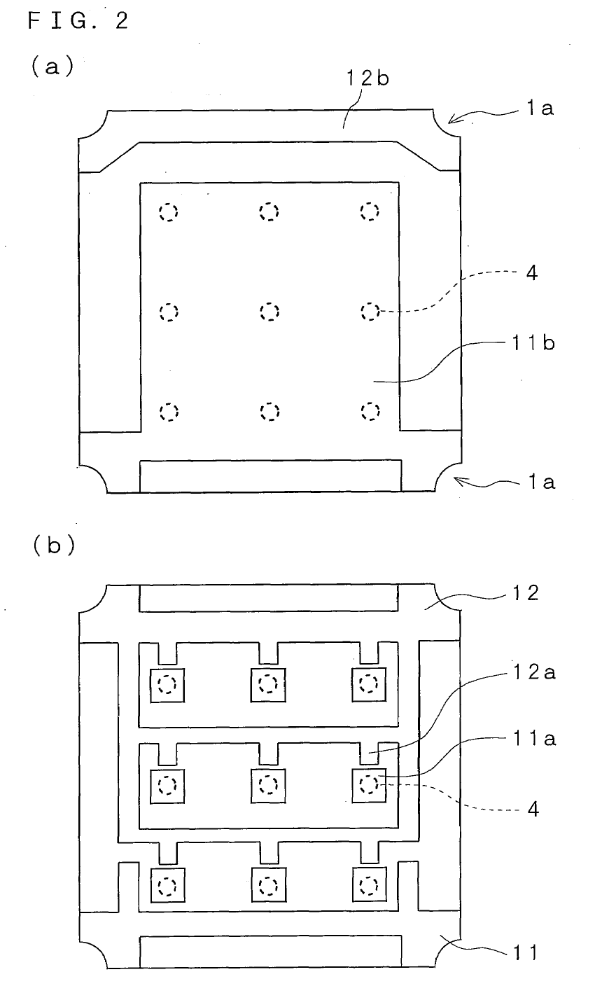

On the surface of the substrate 1, the terminal electrodes 11 and 12, made of Ag, Au or the like, are formed, and an explanation of patterns of the terminal electrodes 11 and 12 will be given below in reference to FIG. 2 showing the back surface and the surface of the substrate. As shown in a explanatory figure of the back surface of the substrate of FIG. 2(a), the back surface electrodes 11b and 12b are formed on the back surface of the substrate 1, and the terminal electrodes 11 and 12 are connected to the back surface electrodes 11b and 12b by side electrodes (not shown in the figures) formed on inner sides of the through holes 1a, thereby a device of a surface mounting type is formed which is mounted directly on a mounting board or the like by soldering or the like.

In addition, the patterns of the first terminal electrode 11 and the second terminal electrode 12 of the surface side are covered mostly with the reflecting wall 3 and only parts not covered are drawn in the example shown in FIG. 1(a), however, as shown by the explanatory figure of the substrate surface of FIG. 2(b), actually the first terminal electrode 11 is provided at two corner side of four corners of the surface, the pattern is not to connect the LED chips 2 directly to the first terminal electrode 11, and the LED chips 2 are connected to the first terminal electrode 11 through the first bonding sections 11a electrically connected to the first terminal electrode 11, the through holes 4 and the back surface electrodes 11b. on the other hand, the second terminal electrode 12 is provided at another two corner side, where the first terminal electrode 11 is not provided, on the surface, and has the second bonding sections 12a reaching the vicinity of the positions for providing the LED chips 2.

The first terminal electrode 11 and the second terminal electrode 12 are not limited to this shape, and by forming the through holes not at four corners but at a center part of each of two sides opposing to each other, the first terminal electrode 11 and the second terminal electrode 12 may be formed so as to extend only to opposing two sides. Further, the terminal electrodes 11 and 12 may be formed by providing lead frames or leads in place of such metal films.

The first bonding sections 11a are formed at positions where each of the plurality of LED chips 2 is to be arranged on the surface of the substrate by patterning concurrently with the same material as that of the terminal electrodes 11, 12 or the like, and electrically connected to the first terminal electrode 11 through the through holes 4 for heat dissipation filled with a electrically conductive material having a larger thermal conductivity than that of the substrate 1 made of silver or the like which are provided in the through holes in the substrate 1 right under the first bonding sections 11a, the back surface electrode 11b, and side electrodes not shown in the figures formed on inner surfaces of the through holes 1a of corners of the substrate where the first terminal electrodes 11 is formed. In addition, the second bonding sections 12a are formed at the vicinity of the first bonding sections 11a as parts of the second terminal electrode 12. In addition, since number of the LED chips 2 may be also varied properly depending on necessity, number or a shape of each of the bonding sections 11a and 12a is varied properly correspondingly thereto.

In addition, a pattern shape of electrodes including the first terminal electrode 11 and the second terminal electrode 12 of FIG. 2 is an example for connecting the plurality of chips in parallel, however other patterns may be allowed such as, for example, a pattern in which the LED chips 2 are bonded to the first terminal electrode 11 not through the back surface electrode 11b or the through holes 4 for heat dissipation, and a pattern in which the LED chips are bonded directly on the through holes 4 for heat dissipation without providing the first bonding sections 11a. In addition, in case of connecting the plurality of chips in series, a pattern of the terminal electrodes can be changed freely so as to form a series connection.

In the example shown in FIG. 1, at the parts of the substrate 1 where the LED chips 2 are provided, namely right under the first bonding sections 11a, through holes are formed, and the through holes 4 for heat dissipation are formed by filling the through holes with a metal such as Ag, Au, Cu or the like, or an electrically conductive material having a larger thermal conductivity than that of the substrate. The reason why the through holes 4 are formed is that, in case of using a sintered body of alumina for the substrate 1, the thermal conductivity is required to be enhanced since the thermal conductivity becomes low comparing to a metal substrate or an AlN substrate. In addition, it is to realize a parallel connection simply by connecting the back surface electrode 11b provided on the back surface of the substrate to the pattern of the first bonding sections 11a provided on the surface of the substrate. It is preferable that the through holes 4 are provided with a diameter of, for example, approximately 0.1 to 0.5 mm and right under the first bonding sections 11a where each of the LED chips 2 is bonded because heat dissipation of each of the LED chips 2 can be achieved surely, and they may be changed properly. By using such structure, heat dissipation by the thermal conduction to the substrate 1 can be improved and, at the same time, the plurality of chips can be simply connected in parallel.

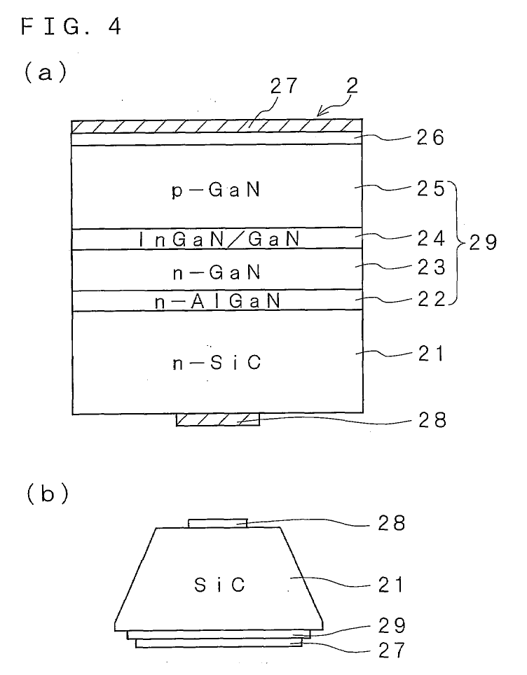

LEDs emitting light of various colors can be used for the LED chips 2, and, in order to obtain white light, a nitride semiconductor light emitting device or the like emitting, for example, blue light or ultraviolet light is used and a light transmitting resin containing a light color conversion material is coated on a surface thereof, thereby the white light can be obtained. A size of each of the LED chips 2 is 0.3 mm square by dividing, for example, a conventional chip of 0.9 mm square into 3×3 pieces. A size of wire bonding on the front surface is required to be approximately 0.1 mm square, and then if number of dividing is too large, there is no significance of dividing, and it is preferable to divide so that one side is approximately 0.2 to 0.4 mm square. In the example, as shown in FIG. 4(b) described later, the chips are formed in a trapezoid having a bottom surface of 0.3 mm square and a front surface of 0.2 mm square. A semiconductor constitution of the LED chips 2 is described later.

The reflecting wall 3 is formed in order to condense light emitted all round from each of the LED chips 2 toward a front side and so as to surround each of the LED chips 2 in the example shown in FIG. 1. Concretely, as shown in FIGS. 1(b) and 1(c), the reflecting wall 3 is provided so as to surround the first bonding section 11a where each of the LED chips 2 is provided and the second bonding section 12a which is electrically connected to each of the LED chips 2 with a wire or the like and formed with a laminate body of a step shape so that a part thereof extends slightly toward an outer side. Namely, the reflecting wall 3 has a grid shape which is formed by hollowing out parts (the first bonding section 11a and the second bonding section 12a) of the substrate 1 where the LED chips 2 are provided, and the part of the grid is formed with a laminated body having a step shape extending slightly from inside. In addition, the part of the grid is formed with a quadrilateral shape, and, at the same time, at an outer periphery (outer periphery of the substrate 1) of the entire chip type semiconductor light emitting device, with a shape (quadrilateral shape in FIG. 1) corresponding to the shape of the outer periphery the chip type semiconductor light emitting device. Of course, the shape is not limited to this but may be varied properly. In addition, number of the parts of the grid is nine in the example shown in FIG. 1 because number of the LED chips 2 is nine, but it may be varied properly according to the number of the LED chips 2.

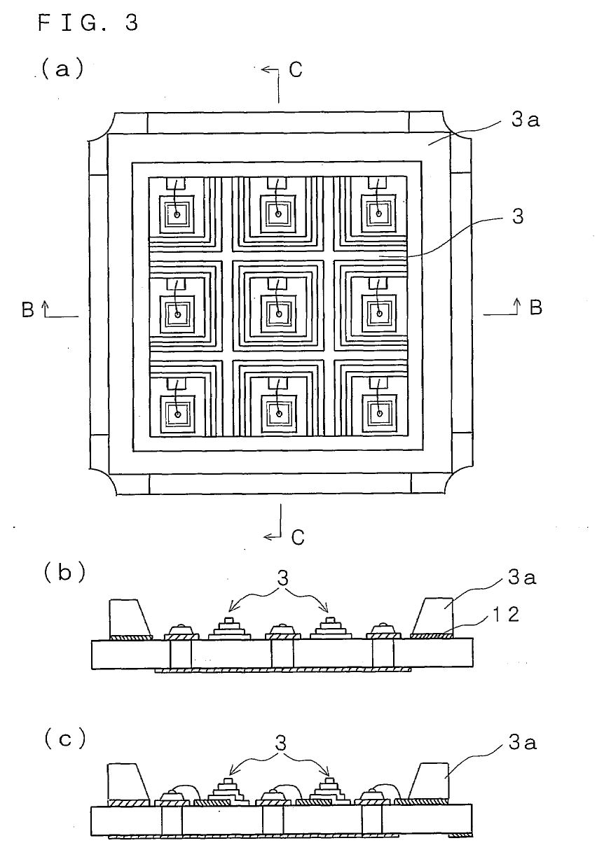

In addition, in the example shown in FIG. 1, the reflecting wall 3 can not be stuck by being formed previously as a reflecting case because it is very small, then, as described later, it is formed by laminating a paste of alumina powder (green mint) or a resin by a screen printing method, therefore it is formed with a step shape. However, as in the example shown in FIG. 3, the reflecting wall of the outer periphery can be stuck as the reflecting wall 3 of a conventional type formed previously.

In addition, the reflecting wall 3 may be formed of a white resin or the like, however it is preferably formed of a sintered body of alumina, including the substrate 1, from the view point of heat dissipation. In order to form the reflecting wall 3 of a sintered body of alumina, by a screen printing method or the like a paste of alumina powder is coated at a position, where the reflecting wall 3 is formed, on the substrate 1, and dried thereafter, by repeating the similar process thereon subsequently with reducing sizes of the opening portions a little, a laminated body is formed by laminating a plurality of layers of the green sheet with a step shape, and thereafter they are sintered together. In such manner, by forming the substrate 1 and the reflecting wall 3 are formed of the same sintered body of alumina, an adhesion property of the substrate 1 and the reflecting wall 3 is superior, and since, even though the sintered body of alumina is inferior in the thermal conductivity compared to a metal plate or AlN, the thermal conductivity is higher than that of the white resin used for a conventional reflecting case by approximately 100 times, heat generated in the LED chips 2 can be transmitted fast from the substrate to the reflecting wall 3, therefore the heat can be dissipated from a large area of the reflecting wall 3.

In addition, the substrate 1 made of the sintered body of alumina has a lower thermal conductivity by approximately one order compared to a metal plate or AlN, however, since heat conduction from the substrate 1 to the mounting board is different according to the mounting board, the sufficient heat conduction to the mounting board can not be always obtained. However, since the heat transmitted to the reflecting wall 3 is dissipated from a large surface area surely, stable heat dissipation can be achieved, and, at the same time, by constituting the substrate 1 and the reflecting wall 3 with the same material, since peeling or the like does not occur because coefficients of the thermal expansion are same, the heat can be dissipated efficiently from the reflecting wall 3, and the efficiency of heat dissipation can be improved in total. Especially, as in the present invention, in case of providing the reflecting wall 3 at each of the plurality of chips, since heat dissipation at the reflecting wall 3 has a large influence to heat dissipation characteristics of the chip type semiconductor light emitting device, forming both of the substrate 1 and the reflecting wall 3 with a sintered body of alumina is very effective.

FIG. 3 are explanatory figures of a plan view and cross-sectional views (cross-sectional views at B-B and C-C in FIG. 3(a)) of another embodiment of the present invention. In this example, the reflecting wall 3 provided at a region except an outer periphery of the substrate 1 are formed by the above-described screen printing method or the like, and thereafter the reflecting case 3a previously formed is stuck only at the outer periphery with a glass binder or the like. In addition, letters and numerals of parts similar to those in FIG. 1 are attached and the explanation is omitted here, however they are the same as those in the example shown in FIG. 1. By using such constitution, since the reflecting wall 3 provided between each of the LED chips 2 is formed by the screen printing method which does not need a large space, the reflecting case 3a which has a smooth inclined surface without any irregularities similar to the conventional one can be stuck at the outer periphery while being formed accurately even in a small space between each of the LED chips 2. Furthermore, since the tall reflection case 3a can be stuck at the periphery, even light which can not be reflected sufficiently by the short reflection wall 3 having irregularities can be utilized by being reflected toward the front surface side perfectly by the reflecting case 3a, and luminance can be more improved.

In the examples shown in FIGS. 1 and 3, the LED chips 2 emitting blue light are used, and as an example of a cross-sectional constitution is shown, for example, in FIG. 4(a), LEDs using nitride semiconductor are formed. However, not being limited to the example, a zinc oxide based (ZnO based) compound or the like may be used. When the chip type semiconductor light emitting device emitting white light is intended to be formed, in case such that the LED chips 2 emit not blue light but ultraviolet light, by coating a resin layer mixed with conversion members (fluorescent material) converting the ultraviolet light into red light, green light and blue light, white light can be also obtained by mixing light of the three primary colors. Even the LED chip emitting ultraviolet light can be similarly formed by using nitride semiconductor or zinc oxide based compound.

Here, the nitride semiconductor means a compound of Ga of group III element and N of group V element or a compound (nitride) in which a part or all of Ga of group III element substituted by other element of group III element like Al, In or the like and/or a part of N of group V element substituted by other element of group V element like P, As or the like. And, the zinc oxide (ZnO) based compound semiconductor means an oxide including Zn, and means concretely besides ZnO, an oxide of one or more elements of group II A and Zn, an oxide of one or more elements of group II B and Zn, or an oxide of elements of group IIA and group IIB and Zn.

The LED chips 2 are used for improving luminance, by dividing a LED having a conventional size, which has (length)×(width)×(height) of, for example, approximately (0.9 mm)×(0.9 mm)×(0.12 mm) into nine, the small LED chips 2 having a size which is, for example, approximately (0.3 mm)×(0.3 mm)×(0.12 mm) are formed, and the semiconductor light emitting device are formed by arranging nine LED chips 2 on the substrate 1 in this case. Of course, a size of chips by dividing can be varied corresponding to a size of the chip type semiconductor light emitting device or the number of chips to be provided on the substrate. In addition, in this example, an outer shape of the LED chip 2 has a longitudinal cross-section of trapezoidal (bottom surface of 0.3 mm square and front surface of 0.2 mm square), however it may be a shape of a rectangular solid or a cube. However, light is apt to be reflected toward the front surface side by a taper shape. In order to form with a trapezoidal shape, for example, at the time of dividing a wafer into chips, by using a blade whose cross-section of a thickness direction is trapezoidal, dicing grooves are formed in a taper shape, then the LED chips 2 with the trapezoidal shape can be obtained. In this case, as described later, if dicing is carried out at a side of epitaxial growth layers, semiconductor layers are apt to be damaged, therefore dicing is carried out from a substrate side (thickness of the LED chip is almost thickness of the substrate) and it is preferable to take out light from the substrate side.

As shown in FIG. 4(a), the LED using nitride semiconductor is provided with a low temperature buffer layer 22 made of, for example, AlGaN based compound (which means various compound that a mixed crystal ratio of Al is changed, including a case of zero and the same applies hereinafter) and having a thickness of approximately 0.005 to 0.1 μm, for example, on an n-type SiC substrate 21. And, there are laminated on the buffer layer 22 in order, an n-type layer 23 made with, for example, an n-type GaN layer or the like, of a thickness of approximately 1 to 5 μm, an active layer 24 having a thickness of approximately 0.05 to 0.3 μm formed with a multiple quantum well (MQW) structure which is formed by laminating 3 to 8 pairs of a well layer made of, for example, In_{0.13}Ga_{0.87}N and having a thickness of 1 to 3 nm, and a barrier layer made of GaN and having a thickness of 10 to 20 nm, and a p-type layer 25 made with, for example, a p-type GaN layer and having a thickness of approximately 0.2 to 0.3, thereby a semiconductor lamination portion 29 is formed. Then, on a surface of the p-type layer 25, a light transmitting conductive layer 26 made of, for example, ZnO is provided with a thickness of approximately 0.1 to 10 μm, on a part of a surface thereof, a p-side electrode 27 is provided with a lamination structure of Ti/Au, Pd/Au or the like with a total thickness of approximately 0.1 to 1 μm, and an n-side electrode 28 is provided with a lamination structure of Ti/Al or Ti/Au, or the like with a total thickness of approximately 0.1 to 1 μm. In addition, in case of forming a chip of the above-described trapezoidal shape, as a schematic view is shown in FIG. 4(b), it is preferable to form the n-side electrode 28 small, the p-side electrode 27 large, and the SiC substrate in a taper shape, so as to emit light from a back surface side of the SiC substrate 21.

Although a SiC substrate is used as a substrate in the above-described example, not being limited to the material, other semiconductor substrate such as GaN, GaAs or the like can be used and also a sapphire substrate can be used. In case of a semiconductor substrate made of SiC or the like, as shown in FIG. 4, an electrode of one side can be provided on a back surface of the substrate, however, in case of an insulating substrate made of material such as sapphire, a conductivity type layer (n-type layer 23 in a constitution of FIG. 4(a)) of a lower layer is exposed by removing a part of laminated semiconductor layers by etching, and an electrode is formed on the exposed portion. In addition, in case of using a semiconductor substrate, an n-type substrate is used and an n-type layer is formed as a lower layer in the above-described example, however the substrate and the lower layer may be formed so as to have a p-type conductivity type. And, a material of the buffer layer 22 is not limited to the AlGaN based compound and other nitride semiconductor layer, other semiconductor layer or the like may be used. When the substrate 21 of the LED 2 is an insulating substrate, connection to the pair of the terminal electrodes 11 and 12 which is provided on the insulating substrate 1 described above, is carried out by wire bonding for both or can be connected directly to both of terminal electrodes 11 and 12 with adhesive by a face down method.

Furthermore, the n-type layer 23 and the p-type layer 25 are not limited to a GaN layer described above, AlGaN based compound or the like may be used, and, in stead of forming each of the layers with single layer, complex layers can be formed which are formed with a material which can easily confine carriers such as AlGaN based compound having large band gap energy at an active layer side and a GaN layer or the like which is apt to raise carrier concentration at an opposite side of the active layer. In addition, a material for the active layer 24 is selected depending upon a desired wavelength of light, a structure is not limited to a MQW structure and a SQW structure or a bulk layer may be formed. Furthermore, a material of the light transmitting conductive layer 26 is not limited to ZnO, ITO or a thin alloy film having a thickness of 2 to 100 nm made of Ni and Au can be used, and a material which can transmit light and diffuse current to whole part of a chip can be used. A Ni—Au layer is formed thin since the layer loses light transmission by a metal layer when the layer is formed thick, however, a ZnO or ITO layer can be allowed to be thick because they transmit light. Of course, as shown in FIG. 4(b), in case of taking out light from a side of the substrate 21, the light transmission is not necessary, therefore Ni—Au layer or the like can be formed thick for the p-side electrode.

By die bonding (mounting) each of the LED chips 2 respectively on the first bonding section 11a provided on the through holes 4 (nine places in the example shown in FIG. 1) for heat dissipation which are connected to the first terminal electrode, for example, through a connection means such as a conductive adhesive, the upper electrode (p-side electrode 27) of each of the LED chips 2 is electrically connected to the first terminal electrode 11, and an electrode (n-side electrode 28) of the substrate 21 side of each of the LED chips 2 is electrically connected to the second bonding section 12a of the second terminal electrode 12 through a wire 7 made of Au or the like, thereby each of the chips is connected in parallel by a relationship of the first terminal electrode 11 and the second terminal electrode 12.

The reflecting wall 3 and the reflecting case 3a, described above, are formed on the substrate 1 by a screen printing method, a glass binder or the like, and the plurality of LED chips 2 are bonded and wire bonded, thereafter a resin mixed with a light color conversion member (fluorescent) is filled so as to coat a portion of each of the LED chips 2 and each of the wires 7 exposed in the reflecting wall 3, thereby blue light emitted in the LED chips 2 can be converted into white light. Namely, there can be used for the light color conversion member, a red color conversion member converting blue light into red light such as yttrium oxide or the like activated by europium, and a blue color conversion member such as an aluminate fluorescent material of an alkaline earth group activated by, for example, bivalent manganese and europium, and a sealing resin layer not shown in the figures is formed by filling a light transmitting resin such as a silicone resin, an epoxy resin or the like mixed with the light color conversion members in the reflecting wall 3. In addition, when the LED chips 2 emit ultraviolet light, besides, for example, the above-described light color conversion member converting ultraviolet light into red light and green light, by mixing a light color conversion member for converting ultraviolet light into blue light such as a halophosphate fluorescent material, an aluminate fluorescent material or the like using cerium, europium or the like for an activator, ultraviolet light is converted into red light, green light and blue light, and white light can be obtained by mixing them. In addition, in case of not converting light color, the LED chips are sealed with a light transmitting resin.

Subsequently, a method for manufacturing the chip type semiconductor light emitting device will be given below. Firstly, on a large green sheet (sheet for a large number of devices) having a thickness of approximately 0.3 mm, penetrations for forming the through holes 4 for heat dissipation are formed and penetrations for the through holes la are formed by punching, metal films for the terminal electrodes 11 and 12 are formed on a surface thereof, and the penetrations for the through holes 4 for heat dissipation are filled with a metal material such as Ag or the like, thereby the substrate 1 on which a pattern of the terminal electrodes shown in FIG. 2(b) is formed. In addition, on the back surface of the green sheet, the back surface electrodes 11b and 12b are provided so as to be connected to the terminal electrodes 11 and 12 formed on the surface of the substrate 1.

Subsequently, for example, by a screen printing method or the like, a paste of alumina powder is coated so as to surround each of positions on the substrate where chips are provided and dried thereafter. By using a mask having slightly smaller openings, the paste of alumina is further coated thereon and dried. This process is repeated several times, the reflecting wall 3 is laminated stepwise so as to be gradually narrower toward the front surface, and thereafter sintered at a temperature of approximately 600 to 700° C., thereby the reflecting wall 3 is formed of a sintered body of alumina and with a grid shape, together with the substrate 1. In addition, there may be another method such that the reflecting wall 3 except at a circumference of the chip type semiconductor light emitting device is formed by the above-described screen printing method, and as for the reflecting case 3a of the circumference, for example, the reflecting case 3a formed porous with a sintered body of alumina is stuck with a glass binder or the like. By forming porous, a reflection coefficient and heat dissipation property are improved. The reflecting wall 3 has an object to reflect light traveling laterally so as to emit light which is emitted from the LED chips 2 toward the front surface side totally. In addition, in case of forming the substrate 1 and the reflecting wall 3 with a white resin without using the sintered body of alumina, after coating and laminating, adhesion can be achieved by baking at a temperature of approximately several hundreds ° C.

Thereafter, the LED chips 2 emitting blue light or ultraviolet light are mounted on the first bonding sections 11a provided on the through holes 4 for heat dissipation on a surface of the insulating substrate 1, and the electrodes (a p-side electrode and an n-side electrode) of each of the LED chips are electrically connected respectively. In the example shown in FIG. 1, the p-side electrode of each of the LED chips 2 is connected to the first bonding section 11a through an electrically conductive adhesive or the like, thereby the p-side electrode is electrically connected to the first terminal electrode 11 through the through hole 4 for heat dissipation, and the n-side electrode (electrode of a side of the substrate) are electrically connected to the second terminal electrodes 12 by bonding using a connection means such as a wire 7 or the like.

Thereafter, the sealing resin layer including light color conversion members is formed by coating so as to coat exposed surfaces of the front surface of each of the LED chips 2 and inner surfaces of the reflecting wall 3 by, for example, a dispenser or the like. The sealing resin is formed with, for example, a resin mixed with a green light conversion member converting blue light into green light and a red color conversion member converting blue light into red light. As a coating method, a transfer method by a transfer pin may be used in place of coating by the dispenser.

As described above, the present invention is characterized in a structure in which the plurality of LED chips 2 formed by dividing a conventional LED chip small are provided on the substrate 1 and the reflecting wall 3 are provided at a surrounding of each of the LED chips 2. Namely, since each of the LED chips 2 emits light all around from a light emitting portion, light is usually emitted upward and also from sides. Then, since the light emitted from the sides is reflected upward by the reflecting wall 3, the light from the sides can contribute to light emitting without any waste. In addition, according to the present invention, not by using one large chip as conventional, but by dividing the chip into the small LED chips 2 and providing the reflection wall 3 at the surrounding of each of the LED chips 2, area of the sides can be enlarged compared to the conventional structure, and a total quantity of the light emitted from the sides can be increased.

In addition, if one large chip is used and a reflecting case is provided at a surrounding thereof, light attenuates by absorption or the like during traveling from the inside of the chip to sides, and, at the same time, even as for the light emitted from the sides, since a distance of the chip and the reflecting case is large, a loss of light in the light emitted from the sides may occur during traveling to the reflecting case. However, by the present invention, since the LED chips 2 are formed small by being divided and provided separately, and the reflecting wall 3 is provided at the surrounding of each of the LED chips 2, attenuation in each of the LED chips 2 is small, the light can be reflected almost perfectly upward at the reflecting wall 3 because the distance of the chip and the reflecting wall is small and the loss of the light hardly occurs. As a result, concretely, luminance can be improved by approximately 20% compared to the case of using one large chip. In addition, by forming the LED chips by being divided with small size, it is supposed that area of the surface covered by wire bonding increases because wire bonding of each LED chip is necessary, however, also in case of one large LED chip, it is necessary to provide metal wiring from a wire bonding section radially in order to spread current to the entire chip, and the loss thereby is not so different.

In addition, not by surrounding only a periphery of the entire chip type semiconductor light emitting device, but by providing individually the reflection wall 3 at a periphery of each of the plurality of LED chips 2 provided on the substrate, light emitted from each of the LED chips 2 is reflected upward by the reflecting wall 3 near each of the LED chips respectively. In addition, since regions separated by the reflecting wall 3 are divided small corresponding to number of the chips, point light sources are dispersed in a surface. As a result, an entire of a large region of the substrate 1 emits light uniformly, as the chip type semiconductor light emitting device, distribution of luminance in the surface becomes extremely uniform, and the distribution of luminance in the surface is significantly improved compared to that in case of using one conventional large chip.

Furthermore, as in a conventional type, if a chip of a large size is used and the reflecting case is provided at a periphery of the substrate, thermal conduction is inferior in the chip at a time of large current drive, and heat can not be dissipated sufficiently through the reflecting case because a distance from the chip to the reflecting case is large, then there arises a problem of deterioration of reliability caused by deterioration of the chip by the heat. In the present invention, by dividing into a plurality of LED chips 2, and providing on the substrate 1 dispersed, and providing the reflecting wall 3 at the vicinity thereof, the heat generated in each of the LED chips 2 can be dissipated through the reflecting wall 3 right soon. In addition, since the LED chips are provided on the substrate 1 dispersed, a region of generating heat is dispersed in a large area of the substrate, then deterioration by the heat can be prevented.

In the above-described example, in order to emit white light by using a LED chip emitting blue light or ultraviolet light, a light color conversion resin is used for a sealing resin to protect a wire or the like, however the present invention is not limited to the white light emitting device and can be applied to semiconductor light emitting devices being apt to generate heat at high luminance.

### INDUSTRIAL APPLICABILITY

The present invention can be used for light sources of a wide field such as backlights for liquid display devices or the like, light emitting devices of various kinds for white light, blue light or the like, and lighting devices or the like.

What is claimed is:

1. A chip type semiconductor light emitting device comprising:
a substrate;
a pair of terminal electrodes provided electrically separately at both end portions of one surface of the substrate which are opposite to each other;
a plurality of light emitting device chips provided separately on the one surface of the substrate and connected to the pair of terminal electrodes; and
a reflecting wall provided so as to surround a surrounding of each of the plurality of light emitting device chips.

2. The chip type semiconductor light emitting device according to claim 1, wherein the reflecting wall surrounding each of the light emitting device chips is formed so that an inner circumference of the reflecting wall at a side of the light emitting device chips is smaller than that at a front surface side away from the light emitting device chips.

3. The chip type semiconductor light emitting device according to claim 1, wherein at least a part of the reflecting wall is formed with a laminated body formed by coating a paste material.

4. The chip type semiconductor light emitting device according to claim 3, wherein the part of the reflecting wall is formed by forming the laminated body of the reflecting wall stepwise, thereby an inner circumference of the reflecting wall at a side of the light emitting device chips is smaller than that at a front surface side away from the light emitting device chips.

5. The chip type semiconductor light emitting device according to claim 1, wherein a part of the reflecting wall between adjacent two of the plurality of light emitting device chips is formed with a laminated body formed by coating a paste material and the other part of the reflecting wall which is at an outer circumference of the entire of the plurality of light emitting device chips is formed with a reflecting case which is formed separately and fixed to the substrate.

6. The chip type semiconductor light emitting device according to claim 3, wherein both of the substrate and the part of the reflecting wall are formed with a material whose principal material is a sintered body of alumina.

7. The chip type semiconductor light emitting device according to claim 1, wherein a through hole is formed at a position of the substrate where each of the light emitting device chips is to be provided and the through hole is filled with a material having a larger thermal conductivity than that of the substrate, thereby a through hole for heat dissipation is formed.

8. The chip type semiconductor light emitting device according to claim 7, wherein the through hole is filled with electrically conductive material, one electrode of each of the light emitting device chips is connected to a back surface electrode provided on a back surface of the substrate through the through hole for heat dissipation, and the back surface electrode is connected to one of the pair of terminal electrodes.

9. The chip type semiconductor light emitting device according to claim 1, wherein each of the light emitting device chips is formed in a quadrilateral shape having a size such that one side of a front surface or a back surface of each of the light emitting device chips is 0.2 to 0.4 mm.

10. The chip type semiconductor light emitting device according to claim 1, wherein a shape of a longitudinal cross section of each of the light emitting device chips mounted on the one surface of the substrate is trapezoidal, and each of the light emitting device chips is mounted on the substrate so that a side of the substrate is a long side of the trapezoid and a surface side opposite to the substrate is a short side.

11. The chip type semiconductor light emitting device according to claim 1, wherein each of the light emitting device chips is formed so as to emit blue light or ultraviolet light, and a light transmitting resin containing a light color conversion member which converts the emitted light to white light is provided on each of the light emitting device chips.

12. The chip type semiconductor light emitting device according to claim 1, wherein the plurality of light emitting device chips are connected in parallel between the pair of terminal electrodes.

13. The chip type semiconductor light emitting device according to claim 1, wherein the plurality of light emitting device chips are connected in series between the pair of terminal electrodes.
